(19) United States
(12) Patent Application Publication
(10) Pub. No.: US 2023/0135946 A1
(43) Pub. Date: May 4, 2023

(54) Self-Aligned Gate Contact Fin Field Effect Transistor and Method for Manufacturing the Same

(71) Applicant: Shanghai Huali Integrated Circuit Corporation, Shanghai (CN)

(72) Inventor: Wenyin Weng, Shanghai (CN)

(73) Assignee: Shanghai Huali Integrated Circuit Corporation, Shanghai (CN)

(21) Appl. No.: 17/952,916

(22) Filed: Sep. 26, 2022

(30) Foreign Application Priority Data
Nov. 4, 2021 (CN) 202111300690.9

(51) Int. Cl. H01L 29/66; H01L 21/8238

(52) U.S. Cl. CPC H01L 29/6659; H01L 21/823814; H01L 29/6681; H01L 29/66545

(57) ABSTRACT

The present application discloses a self-aligned gate contact fin field effect transistor. A work function metal layer and a metal conductive material layer of a gate structure are etched back and a first top trench is formed in a top. The first top trench is filled with a first cap layer. A self-aligned gate contact metal zero layer formed in the first top trench is formed on a top of more than one fin intersecting with a gate metal strip. Sidewalls are formed on two sides of a gate trench. The sidewalls include an air sidewall. A source/drain contact metal zero layer spans each fin and is in a strip structure. Each source/drain contact metal zero layer is etched back and a second top trench is formed in a top. The second top trench is filled with a second cap layer.

### CROSS-REFERENCE TO RELATED APPLICATIONS

This application claims priority to Chinese Patent Application No. 202111300690.9, filed on Nov. 4, 2021, the disclosure of which is incorporated herein by reference in its entirety.

### Technical Field

The present application relates to a semiconductor integrated circuit, in particular to a Self-Aligned Gate Contact (SAGC) Fin Field Effect Transistor (FinFET) and a method for manufacturing the same.

### BACKGROUND

Referring to FIG. 1, it illustrates a top view of an existing fin field effect transistor. A plurality of fins 101 are formed on a semiconductor substrate such as a silicon substrate. The fins 101 are formed by patterning the semiconductor substrate. The fins 101 protrude the surface of the semiconductor substrate. Doping is performed in the fins 101 to form a diffusion region. Shallow Trench Isolation (STI) is formed between the fins 101.

The gate structure covers top surfaces and side surfaces of the fins 101. A conductive channel is formed on the surfaces of the fins 101 covered by the gate structure. In FIG. 1, metal conductive material layers of the gate structures of all fin field effect transistors in the same column are connected to form a gate metal strip 102.

Source and drain regions are formed in the fins 101 on two sides of the gate structure, and usually an embedded epitaxial layer is formed in the source and drain regions.

Tops of the source and drain regions are in contact with a source/drain contact metal zero layer (M0) 103.

In order to realize the leading-out of the gate structure, a gate leading-out region 106 needs to be formed outside a device unit region 105. The gate metal strip 102 extends into the gate leading-out region 106. A gate contact metal zero layer 104 is formed in the gate leading-out region 106. The fins 101 are not formed in the gate leading-out region 106, so a device unit structure is not formed.

As can be seen from FIG. 1, the gate leading-out region 106 illustrated in FIG. 1 occupies additional area, which is not conducive to the reduction of the device area.

Referring to FIG. 2, it is a top view of an existing fin field effect transistor. A plurality of fins 201 are formed on a semiconductor substrate such as a silicon substrate. The fins 201 are formed by patterning the semiconductor substrate. The fins 201 protrude the surface of the semiconductor substrate. Doping is performed in the fins 201 to form a diffusion region. STI is formed between the fins 201.

The gate structure covers top surfaces and side surfaces of the fins 201. A conductive channel is formed on the surfaces of the fins 101 covered by the gate structure. Metal conductive material layers of the gate structures of all fin field effect transistors in the same column are connected to form a gate metal strip 202.

Source and drain regions are formed in the fins 201 on two sides of the gate structure, and usually an embedded epitaxial layer is formed in the source and drain regions.

Tops of the source and drain regions are in contact with the source/drain contact metal zero layer 203.

A gate metal strip 202 is led out through a self-aligned gate contact metal zero layer 204 on the top. The self-aligned gate contact metal zero layer 204 is directly formed in top areas of the fins 201. Therefore, the self-aligned gate contact metal zero layer 204 does not need to occupy additional area. Compared with FIG. 1, the area of the fin field effect transistor illustrated in FIG. 2 can be reduced.

However, as can be seen from FIG. 2, in this structure, the spacing between the self-aligned gate contact metal zero layer 204 and the source/drain contact metal zero layer 203 will become smaller, so how to prevent short-circuiting between the self-aligned gate contact metal zero layer 204 and the source/drain contact metal zero layer 203 becomes very important.

At the same time, if the area of the fin field effect transistor is further reduced, the spacing between the source/drain contact metal zero layer 203 and the gate metal strip 202 will also be reduced, so that the parasitic capacitance formed between the gate and the source/drain of the device will increase, which will increase the RC delay of the device.

### BRIEF SUMMARY

The present application is to provide a self-aligned gate contact fin field effect transistor, which can reduce the parasitic capacitance of the device while reducing the size of the device and prevent short-circuiting between the gate and the source/drain, so as to reduce the RC delay of the device. The present application further provides a method for manufacturing a self-aligned gate contact fin field effect transistor.

According to some embodiments in this application, a self-aligned gate contact fin field effect transistor has a plurality of fins, which are formed on a semiconductor substrate.

A plurality of fin field effect transistors are integrated on the semiconductor substrate.

Each fin field effect transistor includes a gate structure, a source region and a drain region.

The gate structure covers front surfaces and side surfaces of the fins in a gate region. The gate structure is formed by superposing a gate dielectric layer, a work function metal layer and a metal conductive material layer. The gate structure is formed in a gate trench. Top surfaces of the work function metal layer and the metal conductive material layer are etched back to a position lower than a top surface of the gate trench. A first top trench is formed in the top surfaces of the work function metal layer and the metal conductive material layer. The first top trench is filled with a first cap layer formed by a first dielectric layer.

The source region and the drain region are formed in the fins on two sides of the gate structure.

The plurality of fins is arranged in parallel. The fin field effect transistors in the same column are aligned. The gate trenches of all fin field effect transistors in the same column are connected together, the first top trenches are connected together and the metal conductive material layers of the gate structures are connected together to form a gate metal strip. A self-aligned gate contact metal zero layer is formed on the top of more than one fin intersecting with the gate metal strip. The self-aligned gate contact metal zero layer is formed by replacing the first cap layer in the first top trench within a formation area of the self-aligned gate contact metal zero layer with a metal.

Sidewalls are formed on two sides of the gate trench. Top surfaces of the sidewalls are located below the top surface of the gate trench. The sidewalls include air sidewalls. The air sidewalls are used to reduce the parasitic capacitance of the fin field effect transistor.

Tops of the source regions and the drain regions of the fin field effect transistors in the same column are respectively formed with corresponding source/drain contact metal zero layers. The source/drain contact metal zero layer spans each fin and is in a strip structure. A top surface of each source/drain contact metal zero layer is lower than top surfaces of the sidewalls. A second top trench is formed in a top surface of the source/drain contact metal zero layer. The second top trench is filled with a second cap layer formed by a second dielectric layer. The materials of the first dielectric layer and the second dielectric layer are different. The second cap layer is used to prevent short-circuiting between the self-aligned gate contact metal zero layer and the source/drain contact metal zero layer.

In some cases, the sidewalls further include first sidewalls and second sidewalls located on two sides of the air sidewalls, the first sidewalls are located on inner sides close to the gate trench, the second sidewalls are located on outer sides far away from the gate trench, and the second cap layer further covers tops of the first sidewalls, the air sidewalls and the second sidewalls.

In some cases, the material of the first sidewalls includes SiCN and the material of the second sidewalls includes SiN.

In some cases, the formation area of each source/drain contact metal zero layer is defined through self-alignment of the sidewalls of two adjacent gate structures.

In some cases, a zeroth layer via (V0) is formed in the top of more than one fin intersecting with the source/drain contact metal zero layer, and the zeroth layer via passes through the second cap layer and is connected with the source/drain contact metal zero layer.

In some cases, the material of the zeroth layer via includes W, Co or Cu.

In some cases, the material of the first cap layer includes SiN;

the material of the second cap layer includes SiO2.

In some cases, the material of the metal conductive material layer includes W;

the material of the source/drain contact metal zero layer includes W, Co or Cu.

In order to solve the technical problem, the method for manufacturing the self-aligned gate contact fin field effect transistor provided by the present application includes the following steps:
step 1: providing a semiconductor substrate formed with a plurality of fins, forming dummy gate structures on the semiconductor substrate, and sequentially forming first sidewalls and third sacrificial sidewalls on two sides of each dummy gate structure, the material of the first sidewalls being different from the material of the third sacrificial sidewalls;
step 2: forming a source region and a drain region of the fin field effect transistor under self-alignment definition of the third sacrificial sidewalls on the two sides of each dummy gate structure; then removing the third sacrificial sidewalls;
step 3: forming fourth sacrificial sidewalls and second sidewalls on side surfaces of the first sidewalls on the two sides of each dummy gate structure, the fourth sacrificial sidewalls being used to define formation areas of air sidewalls, and the material of the fourth sacrificial sidewalls being different from the material of the first sidewalls and the material of the second sidewalls;
step 4: filling a zeroth interlayer film in a spacing area between the dummy gate structures, a top surface of the zeroth interlayer film being in flush with the top surfaces of the dummy gate structures, and the material of the zeroth interlayer film being the same as the material of the fourth sacrificial sidewalls;
step 5: removing the dummy gate structures and forming gate trenches in areas where the dummy gate structures are removed, top surfaces of the first sidewalls, the fourth sacrificial sidewalls and the second sidewalls being located below top surfaces of the gate trenches;
step 6: forming a gate structure in each gate trench, the gate structure being formed by superposing a gate dielectric layer, a work function metal layer and a metal conductive material layer;
step 7: etching back top surfaces of the metal conductive material layer and the work function metal layer to a position lower than a top surface of the gate trench, and forming a first top trench in top surfaces of the work function metal layer and the metal conductive material layer after etched back,
the plurality of fins being arranged in parallel, the fin field effect transistors in the same column being aligned, and the gate trenches of all fin field effect transistors in the same column being connected together, the first top trenches being connected together and the metal conductive material layers of the gate structures being connected together to form a gate metal strip;
step 8: filling the first top trench with a first cap layer formed by a first dielectric layer;
step 9: forming a source/drain contact metal zero layer on tops of the source region and the drain region on two sides of the gate structure, the source/drain contact metal zero layer passing through the zeroth interlayer film and being in contact with the corresponding source region or drain region at the bottom, a bottom area of each source/drain contact metal zero layer being defined through self-alignment of the second sidewalls of two adjacent gate structures,
each source/drain contact metal zero layer being in a strip structure, and each source/drain contact metal zero layer spanning each fin corresponding to each fin field effect transistor in the same column and being in contact with the corresponding source region or drain region at the bottom;
step 10: etching back each source/drain contact metal zero layer, a top surface of the source/drain contact metal zero layer after etched back being lower than top surfaces of the first sidewalls, the fourth sacrificial sidewalls and the second sidewalls;
step 11: removing the zeroth interlayer film between the gate structures to form a second top trench in the top surface of the source/drain contact metal zero layer, and simultaneously removing the fourth sacrificial sidewalls to form air sidewalls, the air sidewalls being used to reduce the parasitic capacitance of the fin field effect transistor, and
sidewalls being formed by superposing the first sidewalls, the air sidewalls and the second sidewalls;
step 12: filling the second top trench with a second cap layer formed by a second dielectric layer, the materials of the first dielectric layer and the second dielectric layer being different, and
the second cap layer being used to prevent short-circuiting between a self-aligned gate contact metal zero layer formed subsequently and the source/drain contact metal zero layer;
step 13: defining a formation area of the self-aligned gate contact metal zero layer, the formation area of the self-aligned gate contact metal zero layer being located on the top of more than one fin intersecting the gate metal strip;
replacing the first cap layer in the first top trench within the formation area of the self-aligned gate contact metal zero layer with a metal to form the self-aligned gate contact metal zero layer.

In some cases, the material of the first sidewalls includes SiCN and the material of the second sidewalls includes SiN.

In some cases, in step 10, the formation area of each source/drain contact metal zero layer after etched back is defined through self-alignment of the second sidewalls of adjacent two gate structures.

In some cases, after the second cap layer is formed in step 12, the method for manufacturing the self-aligned gate contact fin field effect transistor further includes forming a zeroth layer via, and the step of forming the zeroth layer via includes:
defining a formation area of the zeroth layer via;
removing the second cap layer in the formation area of the zeroth layer via to form an opening of the zeroth layer via, a bottom of the opening of the zeroth layer via exposing a top surface of the source/drain contact metal zero layer;
filling a metal layer in the opening of the zeroth layer via to form the zeroth layer via.

In some cases, the material of the zeroth layer via includes W, Co or Cu.

In some cases, the material of the first cap layer includes SiN;

the material of the second cap layer includes SiO2.

In some cases, the material of the metal conductive material layer includes W;

the material of the source/drain contact metal zero layer includes W, Co or Cu.

The leading-out structure of the gate structure in the present application adopts the self-aligned gate contact metal zero layer formed on the top of the fin, so that the self-aligned gate contact metal zero layer can be formed in the device unit region. Compared with the leading-out structure of the gate structure in the prior art which needs to be formed outside the device unit region, the present application can reduce the area occupied by the leading-out structure of the gate structure, thus reducing the size of the device.

In the present application, the work function metal layer and the metal conductive material layer of the gate structure are respectively etched back, the first cap layer is filled in the first top trench after etched back, the source/drain contact metal zero layer is etched back, and the second cap layer is filled in the second top trench after etched back, thus ensuring the isolation between the gate and the source/drain, and preventing short-circuiting between the gate and the source/drain.

In the present application, air sidewalls are formed in the sidewalls of the gate structure. Under the condition that the size of the device continues to shrink, as can be seen from the characteristics that the dielectric constant of the air is smaller than that of the dielectric material, the air sidewalls are conducive to reducing the parasitic capacitance of the device. Therefore, the present application can also reduce the parasitic capacitance of the device at the same time, thus reducing the RC delay of the device.

### BRIEF DESCRIPTION OF THE DRAWINGS

The present application will be described in further detail below in combination with the specific embodiments with reference to the drawings.

FIG. 1 illustrates a top view of an existing fin field effect transistor.

FIG. 2 illustrates a top view of an existing self-aligned gate contact fin field effect transistor.

FIG. 3 illustrates a stop view of a self-aligned gate contact fin field effect transistor according to an embodiment of the present application.

FIG. 4A illustrates a sectional view along line AA in FIG. 3.

FIG. 4B illustrates a sectional view along line BB in FIG. 3.

FIG. 5A to FIG. 5M illustrate sectional views of a device in each step of a method for manufacturing a self-aligned gate contact fin field effect transistor according to an embodiment of the present application.

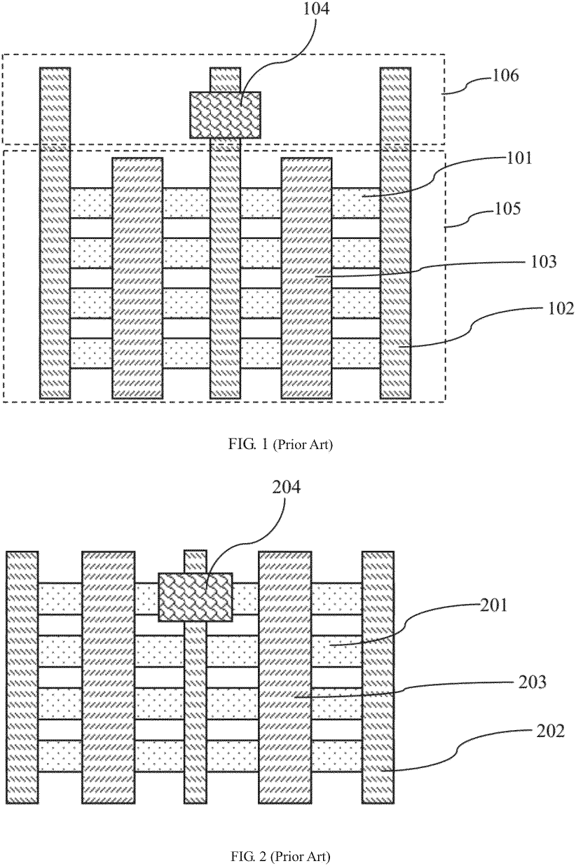

### DETAILED DESCRIPTION

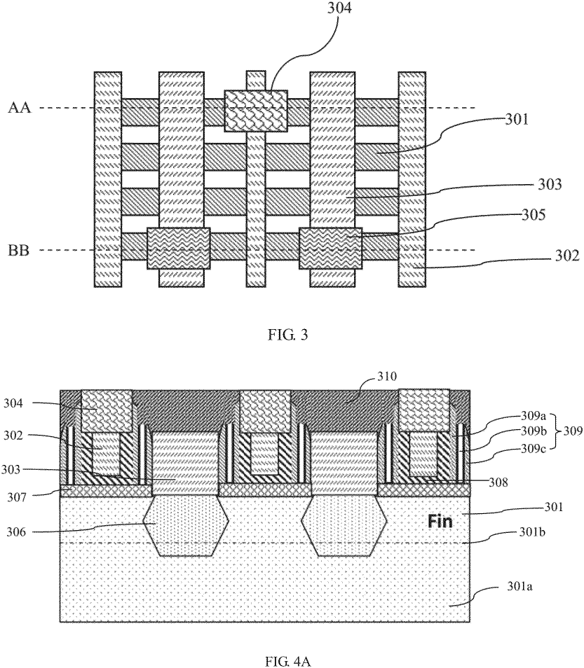

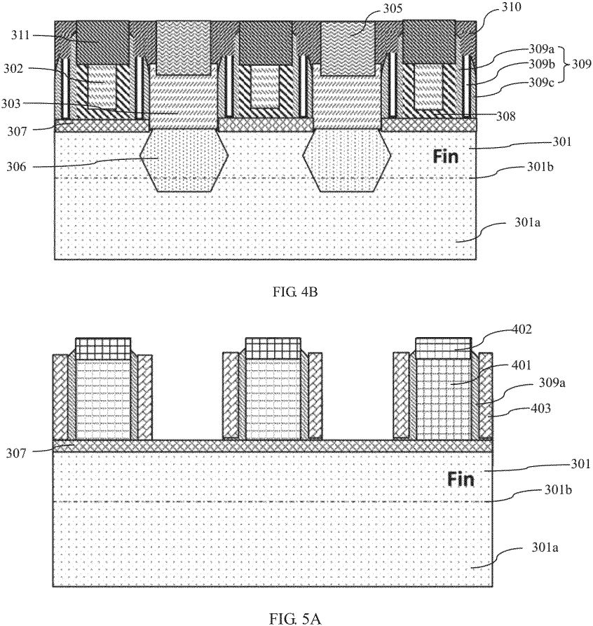

Referring to FIG. 3, it illustrates a top view of a self-aligned gate contact fin field effect transistor according to an embodiment of the present application. FIG. 4A illustrates a sectional view along line AA in FIG. 3. FIG. 4B illustrates a sectional view along line BB in FIG. 3. In the self-aligned gate contact fin field effect transistor according to the embodiment of the present application, a plurality of fins 301 are formed on a semiconductor substrate 301a and a doped diffusion region is formed on the fins 301. The fins 301 are formed by patterning the semiconductor substrate 301a. FIG. 4A illustrates a sectional view along an extension direction of the fins 301. Therefore, the fins 301 and the semiconductor substrate 301a are in an integrated structure. Shallow trench isolation is formed between the fins 301. A dashed line 301b represents the position of a top surface of the semiconductor substrate 301a between the fins 301.

A plurality of fin field effect transistors are integrated on the semiconductor substrate 301a.

Each fin field effect transistor 301 includes a gate structure, a source region and a drain region.

The gate structure covers front surfaces and side surfaces of the fins 301 in a gate region. The gate structure is formed by superposing a gate dielectric layer 307, a work function metal layer 308 and a metal conductive material layer 302. The gate structure is formed in a gate trench. Top surfaces of the work function metal layer 308 and the metal conductive material layer 302 are etched back to a position lower than a top surface of the gate trench. A first top trench is formed in the top surfaces of the work function metal layer 308 and the metal conductive material layer 302. The first top trench is filled with a first cap layer 311 formed by a first dielectric layer.

The source region and the drain region are formed in the fins 301 on two sides of the gate structure. Generally, an embedded epitaxial layer 306 is further formed in formation areas of the source region and the drain region.

The plurality of fins 301 are arranged in parallel. The fin field effect transistors in the same column are aligned. The gate trenches of all fin field effect transistors in the same column are connected together, the first top trenches are connected together and the metal conductive material layers 302 of the gate structures are connected together to form a gate metal strip. A self-aligned gate contact metal zero layer 304 is formed on the top of more than one fin 301 intersecting with the gate metal strip. The self-aligned gate contact metal zero layer 304 is formed by replacing the first cap layer 311 in the first top trench within a formation area of the self-aligned gate contact metal zero layer 304 with a metal.

Sidewalls 309 are formed on two sides of the gate trench. Top surfaces of the sidewalls 309 are located below the top surface of the gate trench. The sidewalls 309 include air sidewalls 309b. The air sidewalls 309b are used to reduce the parasitic capacitance of the fin field effect transistor.

Tops of the source regions and the drain regions of the fin field effect transistors in the same column are respectively formed with corresponding source/drain contact metal zero layers 303. The source/drain contact metal zero layer 303 spans each fin 301 and is in a strip structure. A top surface of each source/drain contact metal zero layer 303 is lower than top surfaces of the sidewalls 309. A second top trench is formed in a top surface of the source/drain contact metal zero layer 303. The second top trench is filled with a second cap layer 310 formed by a second dielectric layer. The materials of the first dielectric layer and the second dielectric layer are different. The second cap layer 310 is used to prevent short-circuiting between the self-aligned gate contact metal zero layer 304 and the source/drain contact metal zero layer 303.

The sidewalls 309 further include first sidewalls 309a and second sidewalls 309c located on two sides of the air sidewalls 309b. The first sidewalls 309a are located on inner sides close to the gate trench. The second sidewalls 309c are located on outer sides far away from the gate trench. The second cap layer 310 further covers tops of the first sidewalls 309a, the air sidewalls 309b and the second sidewalls 309c.

In the embodiment of the present application, the material of the first sidewalls 309a includes SiCN and the material of the second sidewalls 309c includes SiN.

The formation area of each source/drain contact metal zero layer 303 is defined through self-alignment of the sidewalls 309 of two adjacent gate structures.

A zeroth layer via 305 is formed in the top of more than one fin 301 intersecting with the source/drain contact metal zero layer 303. The zeroth layer via 305 passes through the second cap layer 310 and is connected with the source/drain contact metal zero layer 303.

The material of the zeroth layer via 305 includes W, Co or Cu.

The material of the first cap layer 311 includes SiN;

The material of the second cap layer 310 includes SiO2.

The material of the metal conductive material layer 302 includes W;

The material of the source/drain contact metal zero layer 303 includes W, Co or Cu.

The leading-out structure of the gate structure in the embodiment of the present application adopts the self-aligned gate contact metal zero layer 304 formed on the top of the fin 301, so that the self-aligned gate contact metal zero layer 304 can be formed in the device unit region. Compared with the leading-out structure of the gate structure in the prior art which needs to be formed outside the device unit region, the embodiment of the present application can reduce the area occupied by the leading-out structure of the gate structure, thus reducing the size of the device.

In the embodiment of the present application, the work function metal layer 308 and the metal conductive material layer 302 of the gate structure are respectively etched back, the first cap layer 311 is filled in the first top trench after etched back, the source/drain contact metal zero layer 303 is etched back, and the second cap layer 310 is filled in the second top trench after etched back, thus ensuring the isolation between the gate and the source/drain, and preventing short-circuiting between the gate and the source/drain.

In the embodiment of the present application, air sidewalls 309b are formed in the sidewalls 309 of the gate structure. Under the condition that the size of the device continues to shrink, as can be seen from the characteristics that the dielectric constant of the air is smaller than that of the dielectric material, the air sidewalls 309b are conducive to reducing the parasitic capacitance of the device. Therefore, the embodiment of the present application can also reduce the parasitic capacitance of the device at the same time, thus reducing the RC delay of the device.

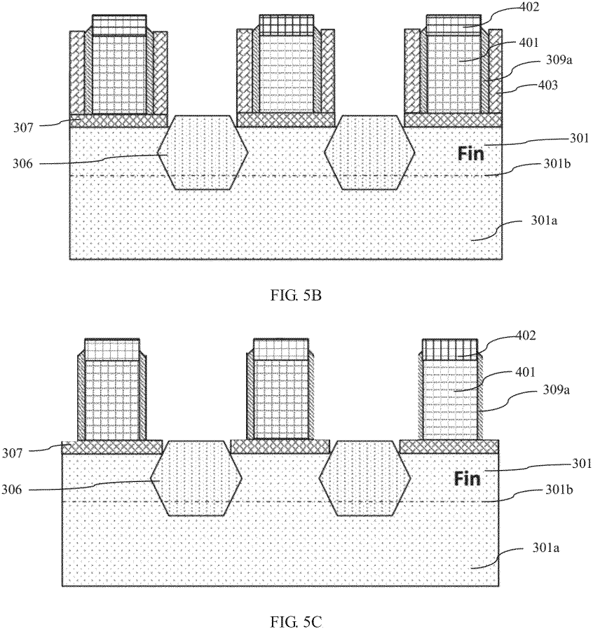

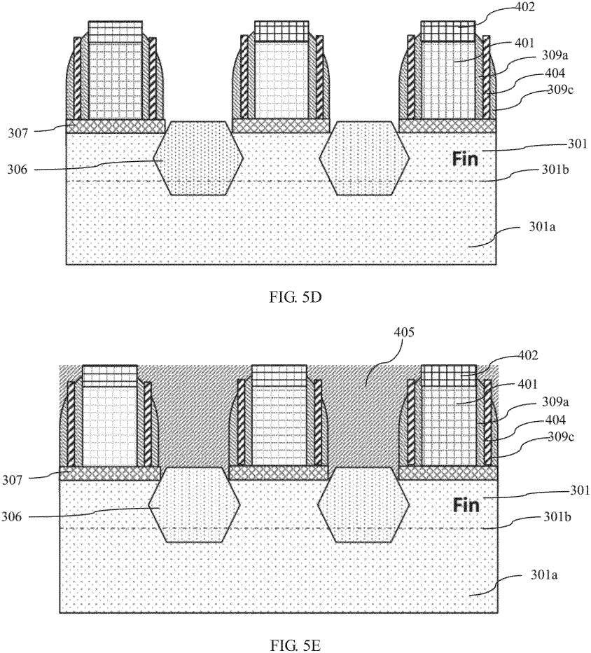

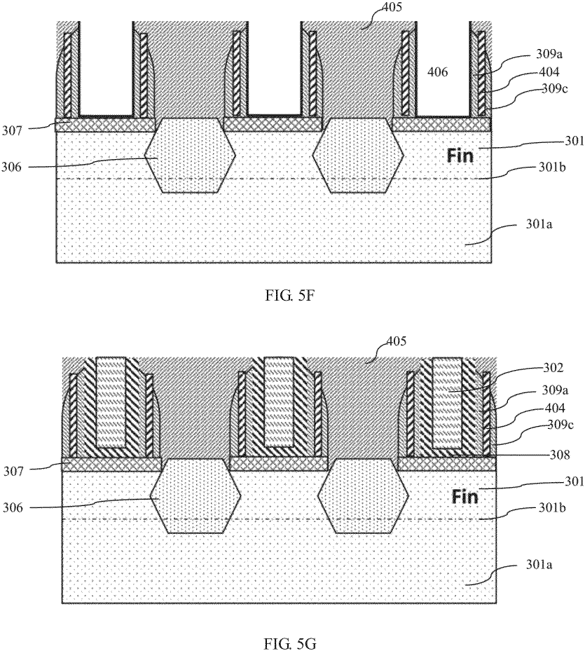

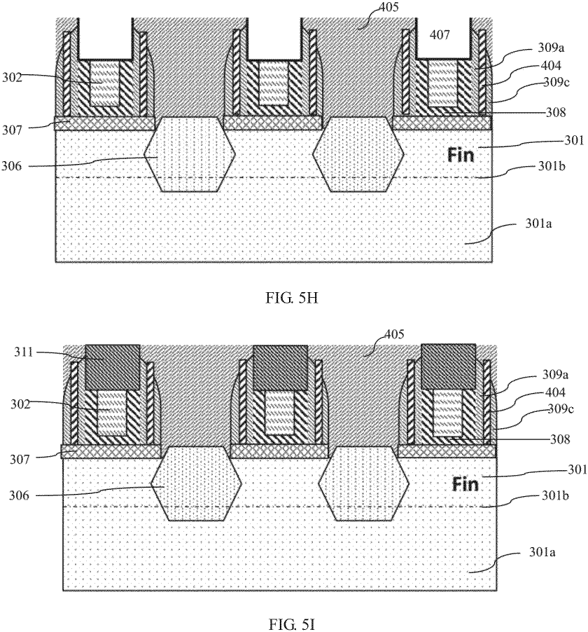

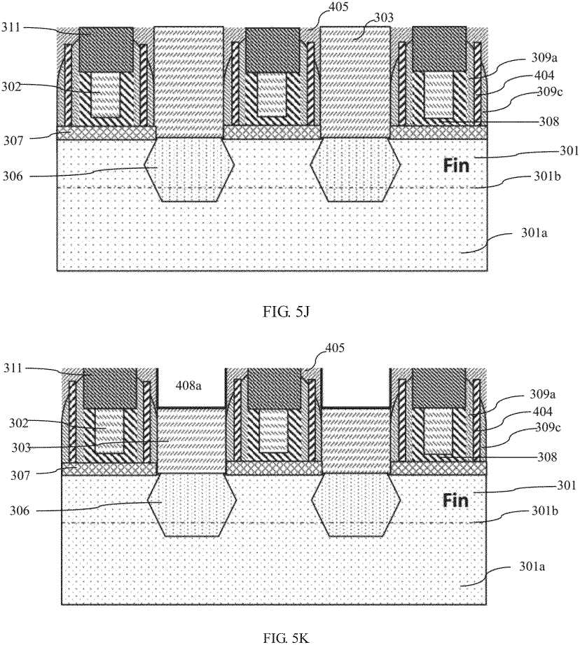

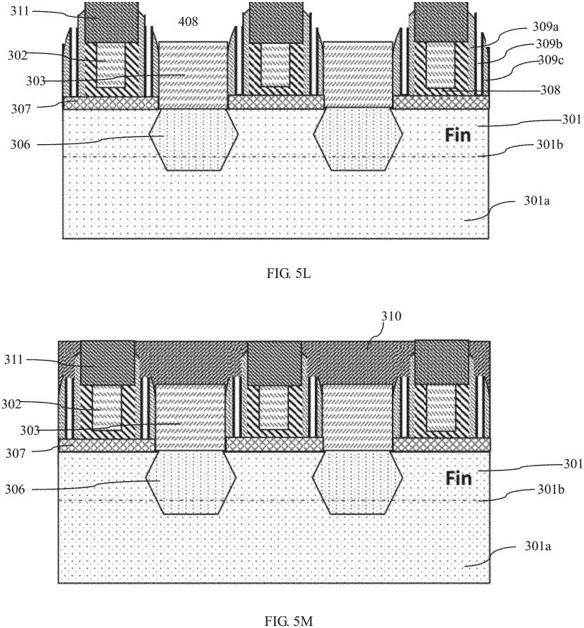

Refer to FIG. 5A to FIG. 5M, which illustrate sectional views of a device in each step of a method for manufacturing a self-aligned gate contact fin field effect transistor according to an embodiment of the present application. The method for manufacturing the self-aligned gate contact fin field effect transistor according to the embodiment of the present application includes the following steps:

In step 1, referring to FIG. 5A, a semiconductor substrate 301a formed with a plurality of fins 301 are provided.

The fins 301 are formed by patterning the semiconductor substrate 301a. FIG. 5A illustrates a sectional view along an extension direction of the fins 301. Therefore, the fins 301 and the semiconductor substrate 301a are in an integrated structure. Shallow trench isolation is formed between the fins 301. A dashed line 301b represents the position of a top surface of the semiconductor substrate 301a between the fins 301.

Dummy gate structures are formed on the semiconductor substrate 301a. Each dummy gate structure includes a dummy dielectric layer and a polysilicon dummy gate 401 superposed sequentially. In the method according to the embodiment of the present application, the dummy gate dielectric layer is directly used as the subsequent gate dielectric layer 307. Further, the dummy gate dielectric layer is an oxide layer and is formed by adopting an In-Situ Steam Generation (ISSG) process. In other embodiments, the structure of the dummy gate dielectric layer, such as material and thickness, is different from the subsequent gate dielectric layer 307. In the subsequent process, the dummy gate dielectric layer will be removed, and then the gate dielectric layer 307 will be formed.

The polysilicon dummy gate 401 is formed through polysilicon deposition and polysilicon etching. Before polysilicon etching, a hard mask layer 402 needs to be formed and patterned. The patterned hard mask layer 402 will define the formation area of the gate structure, and then polysilicon is etched to form the polysilicon dummy gate 401.

First sidewalls 309a and third sacrificial sidewalls 403 are sequentially formed on two sides of each dummy gate structure. The material of the first sidewalls 309a is different from the material of the third sacrificial sidewalls 403. In this way, the etching selection between the first sidewalls 309a and the third sacrificial sidewalls 403 can be realized.

In the method according to the embodiment of the present application, the material of the first sidewalls 309a is SiCN and the material of the third sacrificial sidewalls 403 is SiN.

In step 2, referring to FIG. 5B, a source region and a drain region of the fin field effect transistor are formed under self-alignment definition of the third sacrificial sidewalls 403 on the two sides of each dummy gate structure.

In the method according to the embodiment of the present application, an embedded epitaxial layer 306 is further formed in the formation region of the source region and the drain region. The process of forming the embedded epitaxial layer 306 includes the following steps:

Under the self-alignment definition of the third sacrificial sidewalls 403 on two sides of each dummy gate structure, the fins 301 are etched to form a groove. The shape of the groove is usually Σ-shaped. The depth of the groove may be below a surface 301b.

Then, epitaxial filling is performed to form the embedded epitaxial layer 306.

Then, source/drain implantation is performed to form the source region and the drain region in the embedded epitaxial layer 306. In FIG. 5b, the source region and the drain region are symmetrically formed on two sides of the dummy gate structure.

Referring to FIG. 5C, then the third sacrificial sidewalls 403 are removed.

In step 3, referring to FIG. 5D, fourth sacrificial sidewalls 404 and second sidewalls 309c are formed on side surfaces of the first sidewalls 309a on the two sides of each dummy gate structure. The fourth sacrificial sidewalls 404 are used to define formation areas of air sidewalls 309b. The material of the fourth sacrificial sidewalls 404 is different from the material of the first sidewalls 309a and the material of the second sidewalls 309c, so as to realize the etching selection between the fourth sacrificial sidewalls 404 and the first sidewalls 309a and the second sidewalls 309c.

In the method according to the embodiment of the present application, the material of the second sidewalls 309c is SiN.

In step 4, referring to FIG. 5E, a zeroth interlayer film 408 is filled in a spacing area between the dummy gate structures. A top surface of the zeroth interlayer film 405 is in flush with the top surfaces of the dummy gate structures. Since a hard mask layer 402 is formed on the top of the polysilicon dummy gate 401 of the dummy gate structure, the top surface of the zeroth interlayer film 405 will be in flush with the top surface of the hard mask layer 402. The zeroth interlayer film 405 is formed through a deposition process. The top surface of the zeroth interlayer film 405 will be enabled to be in flush with the top surface of the hard mask layer 402 through - back etching and chemical-mechanical polishing processes.

The material of the zeroth interlayer film 405 is the same as the material of the fourth sacrificial sidewalls 404.

In step 5, referring to FIG. 5F, the dummy gate structures are removed and gate trenches 406 are formed in areas where the dummy gate structures are removed. Top surfaces of the first sidewalls 309a, the fourth sacrificial sidewalls 404 and the second sidewalls 309c are located below top surfaces of the gate trenches 406.

In step 6, referring to FIG. 5G, a gate structure is formed in each gate trench 406. The gate structure is formed by superposing a gate dielectric layer 307, a work function metal layer 308 and a metal conductive material layer 302.

In the method according to the embodiment of the present application, the material of the metal conductive material layer 302 includes W.

In step 7, referring to FIG. 5H, top surfaces of the metal conductive material layer 302 and the work function metal layer 308 are etched back to a position lower than a top surface of the gate trench 406, and a first top trench 407 is formed in top surfaces of the work function metal layer 308 and the metal conductive material layer 302 after etched back.

Referring to FIG. 3, the plurality of fins 301 are arranged in parallel. The fin field effect transistors in the same column are aligned. The gate trenches 406 of all fin field effect transistors in the same column are connected together, the first top trenches 407 are connected together and the metal conductive material layers 302 of the gate structures are connected together to form a gate metal strip.

In step 8, referring to FIG. 5I, the first top trench 407 is filled with a first cap layer 311 formed by a first dielectric layer.

In the method according to the embodiment of the present application, the material of the first cap layer 311 is SiN.

In step 9, referring to FIG. 5J, a source/drain contact metal zero layer 303 is formed on tops of the source region and the drain region on two sides of the gate structure. Te source/drain contact metal zero layer 303 passes through the zeroth interlayer film 405 and is in contact with the corresponding source region or drain region at the bottom. A bottom area of each source/drain contact metal zero layer 303 is defined through self-alignment of the second sidewalls 309c of two adjacent gate structures.

Each source/drain contact metal zero layer 303 is in a strip structure. Each source/drain contact metal zero layer 303 spans each fin 301 corresponding to each fin field effect transistor in the same column and is in contact with the corresponding source region or drain region at the bottom.

In the method according to the embodiment of the present application, the material of the source/drain contact metal zero layer 303 includes W, Co or Cu.

In step 10, referring to FIG. 5K, each source/drain contact metal zero layer 303 is etched back. A top surface of the source/drain contact metal zero layer 303 after etched back is lower than top surfaces of the first sidewalls 309a, the fourth sacrificial sidewalls 404 and the second sidewalls 309c.

As can be seen from FIG. 5K, the formation area of each source/drain contact metal zero layer 303 after etched back is defined through self-alignment of the second sidewalls 309c of adjacent two gate structures.

In step 10, referring to FIG. 5L, the zeroth interlayer film 405 between the gate structures is removed to form a second top trench 408 in the top surface of the source/drain contact metal zero layer 303, and the fourth sacrificial sidewalls 404 are simultaneously removed to form air sidewalls 309b. The air sidewalls 309b are used to reduce the parasitic capacitance of the fin field effect transistor.

Sidewalls 309 are formed by superposing the first sidewalls 309a, the air sidewalls 309b and the second sidewalls 309c.

In step 12, referring to FIG. 5M, the second top trench 408 is filled with a second cap layer 310 formed by a second dielectric layer. The materials of the first dielectric layer and the second dielectric layer are different.

In the method according to the embodiment of the present application, the material of the second cap layer 310 is SiO2.

The second cap layer 310 is used to prevent short-circuiting between a self-aligned gate contact metal zero layer 304 formed subsequently and the source/drain contact metal zero layer 303.

In the method according to the embodiment of the present application, referring to FIG. 4B, after the second cap layer 310 is formed in step 12, the method for manufacturing the self-aligned gate contact fin field effect transistor further includes forming a zeroth layer via 305. The step of forming the zeroth layer via includes the following:

A formation area of the zeroth layer via 305 is defined.

The second cap layer 310 in the formation area of the zeroth layer via 305 is removed to form an opening of the zeroth layer via 305. A bottom of the opening of the zeroth layer via 305 exposes a top surface of the source/drain contact metal zero layer 303.

A metal layer is filled in the opening of the zeroth layer via 305 to form the zeroth layer via 305. Further, the material of the zeroth layer via 305 includes W, Co or Cu.

In step 13, referring to FIG. 4A, a formation area of the self-aligned gate contact metal zero layer 304 is defined. The formation area of the self-aligned gate contact metal zero layer 304 is located on the top of more than one fin 304 intersecting the gate metal strip.

The first cap layer 311 in the first top trench 407 within the formation area of the self-aligned gate contact metal zero layer 304 is replaced with a metal to form the self-aligned gate contact metal zero layer 304.

The present application has been described in detail through specific embodiments, which, however, do not constitute limitations to the present application. Without departing from the principle of the present application, those skilled in the art may also make many modifications and improvements, which should also be considered as included in the scope of protection of the present application.

What is claimed is:

1. A self-aligned gate contact fin field effect transistor, wherein a plurality of fins are formed on a semiconductor substrate; a plurality of fin field effect transistors are integrated on the semiconductor substrate;
each fin field effect transistor comprises a gate structure, a source region, and a drain region;
the gate structure covers front surfaces and side surfaces of the fins in a gate region, the gate structure is formed by superposing a gate dielectric layer, a work function metal layer, and a metal conductive material layer, the gate structure is formed in a gate trench, top surfaces of the work function metal layer and the metal conductive material layer are etched back to a position lower than a top surface of the gate trench, a first top trench is formed in the top surfaces of the work function metal layer and the metal conductive material layer, and the first top trench is filled with a first cap layer formed by a first dielectric layer;
the source region and the drain region are formed in the fins on two sides of the gate structure;
the plurality of fins are arranged in parallel, the fin field effect transistors in a same column are aligned, gate trenches of all fin field effect transistors in the same column are connected together, the first top trenches are connected together and the metal conductive material layers of the gate structures are connected together to form a gate metal strip, a self-aligned gate contact metal zero layer is formed on the top of more than one fin intersecting with the gate metal strip, and the self-aligned gate contact metal zero layer is formed by replacing the first cap layer in the first top trench within a formation area of the self-aligned gate contact metal zero layer with a metal;
sidewalls are formed on two sides of the gate trench, top surfaces of the sidewalls are located below the top surface of the gate trench, the sidewalls comprise air sidewalls, and the air sidewalls are used to reduce a parasitic capacitance of the fin field effect transistor;
tops of the source regions and the drain regions of the fin field effect transistors in the same column are respectively formed with corresponding source/drain contact metal zero layers, the source/drain contact metal zero layer spans each fin and is in a strip structure, a top surface of each source/drain contact metal zero layer is lower than the top surfaces of the sidewalls, and a second top trench is formed in a top surface of the source/drain contact metal zero layer; the second top trench is filled with a second cap layer formed by a second dielectric layer; materials of the first dielectric layer and the second dielectric layer are different; and the second cap layer is used to prevent short-circuiting between the self-aligned gate contact metal zero layer and the source/drain contact metal zero layer.

2. The self-aligned gate contact fin field effect transistor according to claim 1, wherein the sidewalls further comprise first sidewalls and second sidewalls located on two sides of the air sidewalls, the first sidewalls are located on inner sides close to the gate trench, the second sidewalls are located on outer sides far away from the gate trench, and the second cap layer further covers tops of the first sidewalls, the air sidewalls, and the second sidewalls.

3. The self-aligned gate contact fin field effect transistor according to claim 2, wherein a material of the first sidewalls comprises SiCN and a material of the second sidewalls comprises SiN.

4. The self-aligned gate contact fin field effect transistor according to claim 3, wherein a formation area of each source/drain contact metal zero layer is defined through self-alignment of sidewalls of two adjacent gate structures.

5. The self-aligned gate contact fin field effect transistor according to claim 1, wherein a zeroth layer via is formed in the top of more than one fin intersecting with the source/drain contact metal zero layer, and the zeroth layer via passes through the second cap layer and is connected with the source/drain contact metal zero layer.

6. The self-aligned gate contact fin field effect transistor according to claim 5, wherein a material of the zeroth layer via comprises W, Co, or Cu.

7. The self-aligned gate contact fin field effect transistor according to claim 3, wherein a material of the first cap layer comprises SiN, and a material of the second cap layer comprises SiO2.

8. The self-aligned gate contact fin field effect transistor according to claim 1, wherein a material of the metal conductive material layer comprises W, and a material of the source/drain contact metal zero layer comprises W, Co, or Cu.

9. A method for manufacturing a self-aligned gate contact fin field effect transistor, comprising:
step 1: providing a semiconductor substrate formed with a plurality of fins, forming dummy gate structures on the semiconductor substrate, and sequentially forming first sidewalls and third sacrificial sidewalls on two sides of each dummy gate structure, a material of the first sidewalls being different from a material of the third sacrificial sidewalls;
step 2: forming a source region and a drain region of the fin field effect transistor under self-alignment definition of the third sacrificial sidewalls on the two sides of each dummy gate structure; then removing the third sacrificial sidewalls;
step 3: forming fourth sacrificial sidewalls and second sidewalls on side surfaces of the first sidewalls on the two sides of each dummy gate structure, the fourth sacrificial sidewalls being used to define formation areas of air sidewalls, and a material of the fourth sacrificial sidewalls being different from the material of the first sidewalls and a material of the second sidewalls;
step 4: filling a zeroth interlayer film in a spacing area between the dummy gate structures, a top surface of the zeroth interlayer film being in flush with top surfaces of the dummy gate structures, and a material of the zeroth interlayer film being the same as the material of the fourth sacrificial sidewalls;
step 5: removing the dummy gate structures and forming gate trenches in areas where the dummy gate structures are removed, top surfaces of the first sidewalls, the fourth sacrificial sidewalls, and the second sidewalls being located below top surfaces of the gate trenches;
step 6: forming a gate structure in each gate trench, the gate structure being formed by superposing a gate dielectric layer, a work function metal layer, and a metal conductive material layer;
step 7: etching back top surfaces of the metal conductive material layer and the work function metal layer to a position lower than a top surface of the gate trench, and forming a first top trench in top surfaces of the work function metal layer and the metal conductive material layer after etched back,
the plurality of fins being arranged in parallel, fin field effect transistors in a same column being aligned, and gate trenches of all fin field effect transistors in the same column being connected together, the first top trenches being connected together and the metal conductive material layers of the gate structures being connected together to form a gate metal strip;
step 8: filling the first top trench with a first cap layer formed by a first dielectric layer;
step 9: forming a source/drain contact metal zero layer on tops of the source region and the drain region on two sides of the gate structure, the source/drain contact metal zero layer passing through the zeroth interlayer film and being in contact with a corresponding source region or drain region at the bottom, a bottom area of each source/drain contact metal zero layer being defined through self-alignment of second sidewalls of two adjacent gate structures,
each source/drain contact metal zero layer being in a strip structure, and each source/drain contact metal zero layer spanning each fin corresponding to each fin field effect transistor in the same column and being in contact with the corresponding source region or drain region at the bottom;
step 10: etching back each source/drain contact metal zero layer, a top surface of the source/drain contact metal zero layer after etched back being lower than top surfaces of the first sidewalls, the fourth sacrificial sidewalls, and the second sidewalls;
step 11: removing the zeroth interlayer film between the gate structures to form a second top trench in the top surface of the source/drain contact metal zero layer, and simultaneously removing the fourth sacrificial sidewalls to form air sidewalls, the air sidewalls being used to reduce a parasitic capacitance of the fin field effect transistor, and
sidewalls being formed by superposing the first sidewalls, the air sidewalls, and the second sidewalls;
step 12: filling the second top trench with a second cap layer formed by a second dielectric layer, materials of the first dielectric layer and the second dielectric layer being different, and
the second cap layer being used to prevent short-circuiting between a self-aligned gate contact metal zero layer formed subsequently and the source/drain contact metal zero layer;
step 13: defining a formation area of the self-aligned gate contact metal zero layer, the formation area of the self-aligned gate contact metal zero layer being located on the top of more than one fin intersecting the gate metal strip; and
replacing the first cap layer in the first top trench within the formation area of the self-aligned gate contact metal zero layer with a metal to form the self-aligned gate contact metal zero layer.

10. The method for manufacturing the self-aligned gate contact fin field effect transistor according to claim 9, wherein the material of the first sidewalls comprises SiCN and the material of the second sidewalls comprises SiN.

11. The method for manufacturing the self-aligned gate contact fin field effect transistor according to claim 10, wherein, in step 10, a formation area of each source/drain contact metal zero layer after being etched back is defined through self-alignment of the second sidewalls of adjacent two gate structures.

12. The method for manufacturing the self-aligned gate contact fin field effect transistor according to claim 9, wherein after the second cap layer is formed in step 12, the method for manufacturing the self-aligned gate contact fin field effect transistor further comprises forming a zeroth layer via, and the step of forming the zeroth layer via comprises:
defining a formation area of the zeroth layer via;
removing the second cap layer in the formation area of the zeroth layer via to form an opening of the zeroth layer via, a bottom of the opening of the zeroth layer via exposing a top surface of the source/drain contact metal zero layer; and
filling a metal layer in the opening of the zeroth layer via to form the zeroth layer via.

13. The method for manufacturing the self-aligned gate contact fin field effect transistor according to claim 12, wherein a material of the zeroth layer via comprises W, Co, or Cu.

14. The method for manufacturing the self-aligned gate contact fin field effect transistor according to claim 10, wherein a material of the first cap layer comprises SiN, and a material of the second cap layer comprises SiO2.

15. The method for manufacturing the self-aligned gate contact fin field effect transistor according to claim 9, wherein a material of the metal conductive material layer comprises W, and a material of the source/drain contact metal zero layer comprises W, Co, or Cu.
